(19) United States
(12) Patent Application Publication
(10) Pub. No.: US 2017/0073456 A1
(43) Pub. Date: Mar. 16, 2017

(54) POLISHING PAD AND METHOD FOR PRODUCING SAME

(71) Applicant: ROHM AND HAAS ELECTRONIC MATERIALS CMP HOLDINGS, INC., Newark, DE (US)

(72) Inventor: Shinji Shimizu, Osaka (JP)

(73) Assignee: Rohm and Haas Electronic Materials CMP Holdings, Inc., Newark, DE (US)

(21) Appl. No.: 15/125,201

(22) PCT Filed: Jan. 23, 2015
(86) PCT No.: PCT/JP2015/051877

§ 371 Date: Sep. 12, 2016

(30) Foreign Application Priority Data
Mar. 14, 2014 (JP) 2014-051945

(51) Int. Cl. C08G 18/71; C08G 18/42; H01L 21/306; C08G 18/10; C08G 18/32; C08J 9/30; C08G 18/76; C08G 18/48

(52) U.S. Cl. CPC C08G 18/718; C08G 18/7621; C08G 18/4277; C08G 18/4854; C08G 18/10; C08G 18/3206; C08J 9/30; H01L 21/30625; C08G 2101/00

(57) ABSTRACT

The purpose of the present invention is to provide: a polishing pad having a high polishing rate and excellent planarizing properties; and a method for producing the polishing pad. A polishing pad which has a polishing layer comprising a polyurethane resin foam, said polishing pad being characterized in that a polyurethane resin, which is a material used for forming the polyurethane resin foam, has an alkoxysilyl group represented by general formula (1) in a side chain thereof. (In the formula, X represents OR¹ or OH; and R¹'s independently represent an alkyl group having 1 to 4 carbon atoms.)

### TECHNICAL FIELD

The present invention relates to a polishing pad which enables planarization processing, stably with high polishing efficiency, of a material which requires high surface planarity, such as optical materials (such as a lens and reflecting mirror), a silicon wafer, a glass substrate for a hard disc, an aluminum substrate and common metal polishings. The polishing pad of the present invention is preferably used especially for a step of planarizing a device with a silicon wafer having formed thereon an oxide layer, a metal layer and the like prior to further laminating (forming) these layers.

### BACKGROUND ART

As a typical example of material which requires high surface planarity, there can be mentioned a disc of single-crystal silicon, called silicon wafer, used for producing a semiconductor integrated circuit (IC, LSI). In each step of laminating (forming) an oxide layer, a metal layer or the like in the process for producing an IC, LSI and the like, in order to form reliable semiconductor junctions of various thin films used for forming circuits, the surface of a silicon wafer is required to be finished with high accuracy of planarity. Generally in such a step of polish finishing, a polishing pad is fixed on a rotatable support disc called platen, whereas a workpiece (such as a semiconductor wafer) is fixed on a polishing head. And, by creating a relative velocity between the platen and polishing head by the motions of both of them and continuously supplying a polishing slurry comprising abrasive on the polishing pad, polishing operation is carried out.

As the polishing properties of the polishing pad, excellent planarity and in-plane uniformity of the object to be polished as well as high polishing rate are required. The planarity and in-plane uniformity of the object to be polished can be improved, to some extent, by increasing the elastic modulus of the polishing layer. The polishing rate can be improved by employing a foam as the polishing layer to increase the amount of the retained slurry or making the polishing layer hydrophilic to increase the capability for retaining the slurry.

For example, Patent Document 1 suggests, in order to improve the water wettability of a polishing pad, a composition for forming a polishing pad comprising (A) a crosslinkable elastomer, (B) a substance having at least one functional group selected from the group consisting of carboxyl, amino, hydroxyl, epoxy, sulfonic acid and phosphoric acid groups, and a water-soluble substance, wherein the crosslinkable elastomer (A) is a polymer comprising a crosslinked 1,2-polybutadiene.

Patent Document 2 suggests, in order to improve the compatibility of a polishing pad to a slurry, a polishing pad comprising a polyurethane resin composition comprising a polyurethane resin having copolymerized therewith a compound having a hydrophilic group and a hydrophilizing agent, wherein the hydrophilizing agent is at least one member selected from the group consisting of 2,4,7,9-tetramethyl-5-decyne-4,7-diol-di(polyoxyethylene) ether and 2,4,7,9-tetramethyl-5-decyne-4,7-diol and the compound having a hydrophilic group is ethylene oxide monomer.

Patent Document 3 suggests, in order to obtain a polishing pad exhibiting excellent planarity, in-plane uniformity and polishing rate, less change in polishing rate and excellent life properties, the use, as a material component of a polyurethane resin foam, of (B) a hydrophilic isocyanate-terminated prepolymer comprising, as material components, a hydrophilic, high molecular weight polyol component and an isocyanate component, the hydrophilic, high molecular weight polyol component having a number average molecular weight of 500 or more and a content of ethylene oxide units (—CH₂CH₂O—) of 25% by weight.

Patent Document 4 suggests, in order to improve the hydrophilicity of the polishing layer, a polishing layer comprising a partially acylated polysaccharide component which is soluble in an organic solvent in which the resin constituting the polishing layer can be dissolved but sparingly soluble or insoluble in water.

However, there was a problem in that when the polishing layer became hydrophilic, although the polishing rate became high, the planarity of the object to be polished was deteriorated.

### PRIOR ART DOCUMENTS

### Patent Documents

[Patent Document 1] Japanese Patent No. 3826702
[Patent Document 2] Japanese Patent No. 3851135
[Patent Document 3] Japanese Patent No. 4189963
[Patent Document 4] Japanese Patent No. 5189440

### DISCLOSURE OF THE INVENTION

### Problems to be Solved by the Invention

An object of the present invention is to provide a polishing pad which exhibits high polishing rate and excellent planarization properties, and a method for producing the polishing pad.

### Means for Solving the Problems

The present inventors have made intensive and extensive studies for solving the above-mentioned problems. As a result, it has been found that the problems can be solved by the polishing pad described below and, based on this finding, the present invention has been completed.

The present invention relates to a polishing pad having a polishing layer of a polyurethane resin foam, wherein a polyurethane resin used as a material for forming the polyurethane resin foam has, in a side chain, an alkoxysilyl group represented by general formula (1) below:

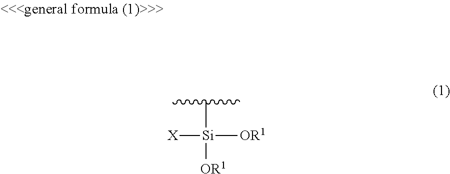

wherein X represents OR¹ or OH, and R¹'s independently represent an alkyl group having 1 to 4 carbon atoms.

As described above, the invention is characterized by introduction of the alkoxysilyl group into the side chain of the polyurethane resin. The alkoxysilyl groups present on the surface of the polishing layer are hydrolyzed by water in the slurry during polishing to thereby yield silanol groups on the surface of the polishing layer. Since these silanol groups are hydrophilic, the hydrophilicity of the surface of the polishing layer is improved. As a result, the capability for retaining the slurry can be improved and the polishing rate can be increased.

Since the alkoxysilyl group is introduced into the side chain of the polyurethane resin, swelling of the polyurethane resin is hard to occur. Further, the alkoxysilyl groups present in the interior portion of the polishing layer is hard to contact with water in the slurry and hard to be hydrolyzed. Therefore, it is possible to make only the surface of the polishing layer hydrophilic, and lowering of hardness of the polishing layer as a whole can be controlled. As a result, lowering of planarization properties of the polishing pad becomes hard to occur.

It is preferred that the polyurethane resin is a product of curing reaction of a polyurethane raw material composition comprising an alkoxysilyl group-containing, isocyanate-terminated prepolymer and a chain extender,

wherein the alkoxysilyl group-containing, isocyanate-terminated prepolymer is a product of reaction of a prepolymer raw material composition comprising:

an isocyanate component comprising an alkoxysilyl group-containing isocyanate represented by general formula (2) below:

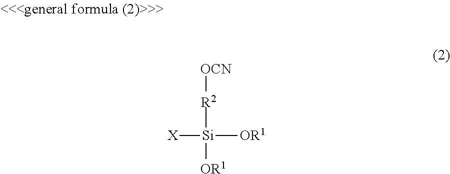

wherein X represents OR¹ or OH, R¹'s independently represent an alkyl group having 1 to 4 carbon atoms, and R² represents an alkylene group having 1 to 6 carbon atoms, and

a polyol component comprising a polyol having a functionality of 3 or more.

It is preferred that the alkoxysilyl group-containing isocyanate is 3-isocyanatopropyltriethoxysilane.

Further, it is preferred that the content of the alkoxysilyl group-containing isocyanate in the polyurethane raw material composition is 1 to 10% by weight. Since the alkoxysilyl group is introduced into the side chain of the polyurethane resin, introduction of a small amount of the alkoxysilyl group causes development of hydrophilicity. When the content of the alkoxysilyl group-containing isocyanate is less than 1% by weight, it becomes difficult to make the surface of the polishing layer hydrophilic. When the content of the alkoxysilyl group-containing isocyanate is more than 10% by weight, it tends to become difficult to produce a polishing layer excellent in polishing properties.

Further, the present invention relates to a method for producing a polishing pad comprising mixing a first component comprising an isocyanate-terminated prepolymer and a second component comprising a chain extender for curing to thereby produce a polyurethane resin foam,

wherein the first component comprises an alkoxysilyl group-containing, isocyanate-terminated prepolymer which is a product of reaction of a prepolymer raw material composition comprising:

an isocyanate component comprising an alkoxysilyl group-containing isocyanate represented by general formula (2) below:

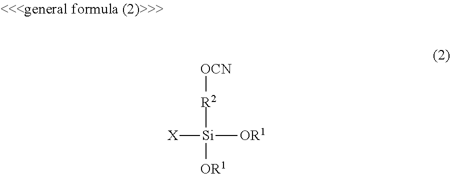

wherein X represents OR¹ or OH, R¹'s independently represent an alkyl group having 1 to 4 carbon atoms, and R² represents an alkylene group having 1 to 6 carbon atoms, and

a polyol component comprising a polyol having a functionality of 3 or more, and

wherein, in the mixing, a silicone-based surfactant is added to the first component in an amount of 0.05 to 10% by weight based on the total weight of the first and second components, the first component is stirred with a non-reactive gas to thereby prepare a gas bubble-dispersed liquid having dispersed therein gas bubbles of the non-reactive gas, and the second component is added to the gas bubble-dispersed liquid for curing to thereby produce a polyurethane resin foam.

It is preferred that the alkoxysilyl group-containing isocyanate is 3-isocyanatopropyltriethoxysilane.

It is preferred that the content of the alkoxysilyl group-containing isocyanate is 1 to 10% by weight in the total weight of the first and second components.

Further, the present invention relates to a method for producing a semiconductor device comprising polishing the surface of a semiconductor wafer using the polishing pad described above.

### Effects of the Invention

The polishing pad of the present invention exhibits high polishing rate and excellent planarization properties. Further, since the surface of the polishing layer of the polishing pad of the present invention becomes hydrophilic by a slurry during the polishing operation, agglomeration of abrasive in the slurry becomes hard to occur and occurrence of scratch on the object to be polished can be effectively controlled.

### BRIEF DESCRIPTION OF THE DRAWINGS

FIG. 1 is a skeleton configuration diagram showing an example of a polishing apparatus used for CMP polishing.

### MODE FOR CARRYING OUT THE INVENTION

The polishing pad of the present invention may comprise only a polishing layer of a polyurethane resin foam, or a laminated body comprising a polishing layer and another layer (such as a cushioning layer).

The polyurethane resin used as a material for forming the polyurethane resin foam has, in its side chain, an alkoxysilyl group represented by general formula (1) below:

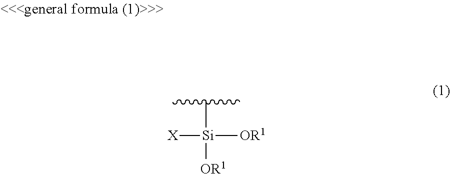

wherein X represents OR¹ or OH, and R¹'s independently represent an alkyl group having 1 to 4 carbon atoms. It is preferred that X is OR¹. It is preferred that R¹ is a methyl or ethyl group.

As a material of the polyurethane resin, in combination with an isocyanate component, a polyol component (high molecular weight polyol and/or low molecular weight polyol) and a chain extender, an alkoxysilyl group-containing compound is used for introducing the alkoxysilyl group represented by general formula (1) above into the side chain of the polyurethane resin. There is no particular limitation with respect to the method for introducing the alkoxysilyl group into the side chain of the polyurethane resin, and as examples of such methods, there can be mentioned 1) a method in which a polyol component having a functionality of 3 or more is reacted with an alkoxysilyl group-containing isocyanate, 2) a method in which an isocyanate component having a functionality of 3 or more is reacted with an alkoxysilyl group-containing alcohol or alkoxysilyl group-containing amine, and 3) a method in which an alkoxysilyl group-containing isocyanate is reacted with a polyurethane resin (allophanate reaction or biuret reaction).

In the present invention, it is preferred that the polyurethane resin is a product of curing reaction of a polyurethane raw material composition comprising an alkoxysilyl group-containing, isocyanate-terminated prepolymer and a chain extender,

wherein the alkoxysilyl group-containing, isocyanate-terminated prepolymer is a product of reaction of a prepolymer raw material composition comprising:

an isocyanate component comprising an alkoxysilyl group-containing isocyanate represented by general formula (2) below:

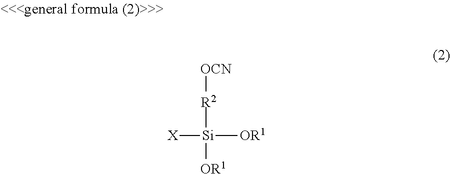

wherein X represents OR¹ or OH, R¹'s independently represent an alkyl group having 1 to 4 carbon atoms, and R² represents an alkylene group having 1 to 6 carbon atoms, and

a polyol component comprising a polyol having a functionality of 3 or more.

It is preferred that 3-isocyanatopropyltriethoxysilane is used as the alkoxysilyl group-containing isocyanate represented by general formula (2) above.

As an isocyanate component other than the alkoxysilyl group-containing isocyanate, any compound conventionally known in the field of polyurethanes can be used with no particular limitation. Examples of such isocyanates include an aromatic diisocyanate, such as 2,4-toluene diisocyanate, 2,6-toluene diisocyanate, 2,2′-diphenylmethane diisocyanate, 2,4′-diphenylmethane diisocyanate, 4,4′-diphenylmethane diisocyanate, 1,5-naphthalene diisocyanate, p-phenylene diisocyanate, m-phenylene diisocyanate, p-xylylene diisocyanate and m-xylylene diisocyanate; an aliphatic diisocyanate, such as ethylene diisocyanate, 2,2,4-trimethylhexamethylene diisocyanate and 1,6-hexamethylene diisocyanate; an alicyclic diisocyanate, such as 1,4-cyclohexane diisocyanate, 4,4′-dicyclohexylmethane diisocyanate, isophorone diisocyanate and norbornane diisocyanate. These compounds may be used individually or in combination.

Examples of the polyols each having a functionality of 3 or more (polyols each having 3 or more hydroxyl groups) include a high molecular weight polyol with the number of functional groups of 3, such as polycaprolactonetriol; a high molecular weight polyol with the number of functional groups of 4, such as polycaprolactonetetraol; trimethylolpropane, glycerin, diglycerin, 1,2,6-hexanetriol, triethanolamine, pentaerythritol, tetramethylolcyclohexane, methyl glucoside and alkylene oxide (EO, PO and the like) addition products of these compounds. These compounds may be used individually or in combination. Among these compounds, use of polycaprolactonetriol is preferred.

As polyol components other than the polyols each having a functionality of 3 or more, there can be mentioned high molecular weight polyols usually used in the technical field of polyurethanes. Examples of such polyols include a polyether polyol typified by a polytetramethylene ether glycol, a polyethylene glycol and the like; a polyester polyol typified by a polybutylene adipate; a polyester polycarbonate polyol exemplified by a product of reaction between a polyester glycol (such as polycaprolactonepolyol and polycaprolactone) and an alkylene carbonate; a polyester polycarbonate polyol obtained by reacting ethylene carbonate with a polyhydric alcohol followed by reaction of the resultant reaction mixture with an organic dicarboxylic acid; and a polycarbonate polyol obtained by a transesterification reaction between a polyhydroxyl compound and an aryl carbonate. These compounds may be used individually or in combination.

There is no particular limitation with respect to the weight average molecular weight of the high molecular weight polyol. However, from the viewpoint of the elastic properties and the like of the resultant polyurethane resin, it is preferred that the weight average molecular weight is from 500 to 3000. When the weight average molecular weight is less than 500, the polyurethane resin obtained using such a polyol exhibits unsatisfactory elastic properties and tends to be a brittle polymer, and a polishing pad of this polyurethane resin may be too hard and cause scratch on the surface of an object to be polished. Further, such a polyol is not preferred from the viewpoint of lifetime of the resultant polishing pad since the polyurethane resin becomes easy to wear. On the other hand, when the weight average molecular weight is more than 3000, the polishing pad of the polyurethane resin obtained using this polyol becomes soft and it becomes difficult to obtain fully satisfactory planarity.

The high molecular weight polyol may be used in combination with a low molecular weight polyol, such as ethylene glycol, 1,2-propylene glycol, 1,3-propylene glycol, 1,2-butanediol, 1,3-butanediol, 1,4-butanediol, 2,3-butanediol, 1,6-hexanediol, neopentylglycol, 1,4-cyclohexanedimethanol, 3-methyl-1,5-pentanediol, diethylene glycol, triethylene glycol, 1,4-bis(2-hydroxyethoxy)benzene, diethanolamine and N-methyldiethanolamine. It may be used in combination with a low molecular weight polyamine, such as ethylenediamine, tolylenediamine, diphenylmethanediamine and diethylenetriamine. Further, it may be used in combination with an alcohol amine, such as monoethanolamine, 2-(2-aminoethylamino)ethanol and monopropanolamine. These compounds, a low molecular weight polyol, low molecular weight polyamine and the like may be used individually or in combination.

The alkoxysilyl group-containing, isocyanate-terminated prepolymer is produced, using the isocyanate component, polyol component and the like so that the ratio (NCO/H*) of the amount (in equivalent) of isocyanate groups (NCO) relative to that of active hydrogens (H*) is within that range of from 1.2 to 8, preferably from 1.5 to 3, by reacting these compounds heating. When this ratio is lower than 1.2, possibility of occurrence of gelation during the production of the prepolymer tends to become high. On the other hand, when this ratio is higher than 8, a large amount of heat is generated during the reaction with the chain extender and it tends to become difficult to obtain a polishing pad with uniformity.

The alkoxysilyl group-containing, isocyanate-terminated prepolymer may be used in combination with an isocyanate-terminated prepolymer containing no alkoxysilyl group.

A chain extender is used for curing the isocyanate-terminated prepolymer. The chain extender is an organic compound having at least 2 active hydrogen groups, and examples of active hydrogen groups include a hydroxyl group, a primary or secondary amino group, a thiol group (SH) and the like. Specific examples of chain extenders include polyamines, such as 4,4′-methylenebis(o-chloroaniline)(MOCA), 2,6-dichloro-p-phenylenediamine, 4,4′-methylenebis(2,3-dichloroaniline), 3,5-bis(methylthio)-2,4-toluenediamine, 3,5-bis(methylthio)-2,6-toluenediamine, 3,5-diethyltoluene-2,4-diamine, 3,5-diethyltoluene-2,6-diamine, trimethyleneglycol-di-p-aminobenzoate, 1,2-bis(2-aminophenylthio)ethane, 4,4′-diamino-3,3′-diethyl-5,5′-dimethyldiphenylmethane, N,N′-di-sec-butyl-4,4′-diaminodiphenylmethane, 3,3′-diethyl-4,4′-diaminodiphenylmethane, m-xylylenediamine, N,N′-di-sec-butyl-p-phenylenediamine, m-phenylenediamine and p-xylylenediamine; and the low molecular weight polyols and low molecular weight polyamines. These compounds may be used individually or in combination.

It is preferred that the content of the alkoxysilyl group-containing isocyanate in the polyurethane raw material composition is 1 to 10% by weight, preferably 1 to 8% by weight, more preferably 1 to 5% by weight.

The polyurethane resin foam can be produced by applying a conventional urethanation technique, such as a melting method, solution method and the like. However, considering cost, working environment and the like, it is preferred that the polyurethane resin foam is produced by melting method.

The polyurethane resin foam can be produced either by a prepolymer method or one-shot method. When a prepolymer method is employed, it is preferred that the ratio of the number of isocyanate groups of the prepolymer relative to the number of the active hydrogen groups (hydroxyl groups and amino groups) of the chain extender is from 0.9 to 1.2.

Examples of methods for producing a polyurethane resin foam include a method in which hollow beads are added, a mechanical foaming method (including a mechanical frothing method), a chemical foaming method and the like.

A mechanical foaming method using a silicone-based surfactant which is a copolymer of a polyalkylsiloxane with a polyether is especially preferred. As examples of compounds suitable as the silicone-based surfactant, there can be mentioned SH-192 and L-5340 (manufactured and sold by Dow Corning Toray Silicone Co., Ltd.), B8443 and B8465 (manufactured and sold by Goldschmidt Chemical Corporation) and the like. It is preferred that the silicone-based surfactant is added to the polyurethane raw material composition so that the concentration is 0.05 to 10% by weight, preferably 0.1 to 5% by weight.

If necessary, to the polyurethane raw material composition, an additive, such as a stabilizer (such as antioxidant), a lubricant, a pigment, a filler, an antistatic agent and the like, may be added.

The polyurethane resin foam may be of a closed cell type or an open cell type. However, in order to prevent infiltration of the slurry into the interior portion of the polishing layer and hydrolysis of the alkoxysilyl groups present in the interior portion of the polishing layer, it is preferred that the polyurethane resin foam is of a closed cell type.

An explanation is made below with respect to an example of production of the microcellular type polyurethane resin foam (constituting the polishing pad (polishing layer)). A method for producing such a polyurethane resin foam has the following steps:

1) Foaming step in which the gas bubble-dispersed liquid of the alkoxysilyl group-containing, isocyanate-terminated prepolymer is prepared

A silicone-based surfactant is added to the alkoxysilyl group-containing, isocyanate-terminated prepolymer (first component), and the resultant mixture is stirred in the presence of a non-reactive gas so that the non-reactive gas is dispersed as gas bubbles, thereby forming the gas bubble-dispersed liquid. When the prepolymer is solid at an ordinary temperature, the prepolymer is preheated to a proper temperature and used in a molten state.

2) Chain extender mixing step

A chain extender (second component) is added to the gas bubble-dispersed liquid and mixed/stirred to thereby form a foaming reaction liquid.

### 3) Casting Step

The forming reaction liquid is cast into a mold.

### 4) Curing Step

The foaming reaction liquid having been cast into the mold is heated and reaction-cured.

It is preferred that the non-reactive gas used for forming gas bubbles is not combustible. As specific examples of such gases include nitrogen, oxygen, a carbon dioxide gas, a rare gas such as helium and argon, and a mixed gas thereof. Dried air (from which water is removed) is most preferable in respect of cost.

Any conventionally known stirrer can be used with no particular limitation as a stirrer for dispersing the non-reactive gas in the first component (containing the silicone-based surfactant). Specific examples of such stirrers include a homogenizer, a dissolver, a twin-screw planetary mixer and the like. There is no particular limitation with respect to the shape of a stirring blade of the stirrer. However, use of a whipper-type stirring blade is preferred since fine gas bubbles are formed.

It is a preferred embodiment that different stirrers are used for the stirring in the foaming step for forming the gas bubble-dispersed liquid and the stirring in the mixing step for mixing the added chain extender. In particular, stirring in the mixing step may not be stirring for forming gas bubbles, and use of a stirrer not causing incorporation of a gas to form large gas bubbles is preferred. As such a stirrer, a planetary mixer is preferred. The same stirrer may be used in the foaming step and mixing step, and it is preferred that the stirrer is used with adjustment of stirring conditions (such as adjustment of revolution rate of the stirring blade), if necessary.

In the method for producing the polyurethane resin foam, it is extremely preferred that the foaming reaction liquid is cast into a mold and heated for reaction until the fluidity is lost and the resultant foam is heated for post-curing, because of the effect of improving the physical properties of the foam. The forming reaction liquid just cast into the mold may be directly put in a heating oven under the conditions for post-curing. Even under such conditions, heat is not immediately conducted to the reactive components, and thus the diameters of cells are not increased. It is preferred that the curing reaction is conducted under ordinary pressure since the shape of cells is stabilized.

A known catalyst promoting the polyurethane reaction, such as a tertiary amine-based one, may be used in the polyurethane resin foam. The type and addition amount of the catalyst are selected considering the time of flowing necessary for casting, after the mixing step, into a mold having a predetermined shape.

Production of the polyurethane resin foam may be conducted in a batchwise manner in which each component is weighed out, introduced into a vessel and mixed, or in a continuous production manner in which each component is continuously supplied into and stirred in a stirring apparatus and the resultant reaction liquid is withdrawn to produce a molded article.

Further, the prepolymer as a material of the polyurethane resin foam may be subjected to a process to form a thin sheet in which the prepolymer is introduced into a reaction vessel, a chain extender is introduced into the vessel, the resultant mixture is stirred and cast into a mold with a predetermined size to thereby form a block, and the block is sliced into a thin sheet using a slicer of a planer-type or band saw-type. Alternatively, the thin sheet may be directly formed in the above-mentioned step of casting into the mold.

It is preferred that the average cell diameter of the polyurethane resin foam is from 30 to 200 μm. If the average cell diameter is out of this range, the planarity of the object to be polished after polishing tends to be lowered.

It is preferred that the polyurethane resin foam has a hardness of 40 to 70 degrees, as measured with an Asker D hardness meter. When the Asker D hardness is less than 40 degrees, the planarity of the object to be polished is lowered, whereas when it is greater than 70 degrees, although the planarity is good, the uniformity of the object to be polished tends to be lowered.

It is preferred that the polyurethane resin foam has a specific gravity of 0.5 to 1.3. When the specific gravity is less than 0.5, the surface strength of the polishing layer is lowered and the planarity of the object to be polished tends to be lowered. On the other hand, when the specific gravity is greater than 1.3, the number of cells on the surface of the polishing layer is lowered and, although the planarity is good, the polishing rate tends to be lowered.

It is preferred that the polishing surface of the polishing pad (polishing layer) of the present invention, which contacts with an object to be polished, has a surface structure for holding and renewing a slurry. Although a polishing layer of a foam itself has many openings on its polishing surface to hold and renew a slurry, it is preferred that the polishing surface has a structure with concavity and convexity in order to provide further holding of a slurry and efficient renewal of a slurry and prevent breaking of an object to be polished caused by adhesion to the object. There is no particular limitation with respect to the structure with concavity and convexity as long as the structure gives a shape which provides capability of holding and renewing a slurry. Examples of such structures include those with X-Y grid pattern grooves, concentric circle-shaped grooves, through-holes, non-through-holes, polygonal prisms, cylinders, spiral grooves, eccentric grooves, radial grooves and a combination of these grooves. These structures are generally arranged with regularity. However, in order to provide desirable capability of holding and renewing a slurry, the pitch, width, depth and the like of the grooves can be changed with respect to each of certain regions.

There is no particular limitation with respect to the method of forming the above-mentioned structure with concavity and convexity. Examples of such methods include a method by mechanical cutting using a jig, such as a cutting tool of a predetermined size; a method by casting, into a mold having a predetermined surface shape, a resin for curing; a method by pressing a resin with a pressing plate having a predetermined surface shape; a method by photolithography; a method using a printing means; and a method by a laser light using a CO₂ gas laser and the like.

The polishing pad of the present invention may be a laminate of a polishing layer and a cushion sheet adhered to each other.

The cushion sheet (cushion layer) supplements the properties of the polishing layer. The cushion sheet is necessary in CMP for striking a balance between the planarity and uniformity which are in a trade-off relationship. This planarity refers to the planarity, after the polishing of an object to be polished having fine concavities and concavities formed during the patterning, of the portion of the object corresponding to the formed pattern, and this uniformity refers to the uniformity of an object to be polished as a whole. Planarity is improved by the properties of the polishing layer, and uniformity is improved by the properties of the cushion sheet. In the polishing pad of the present invention, use of the cushion sheet softer than the polishing layer is preferred.

Examples of cushion sheets include those of a nonwoven fabric, such as a polyester nonwoven fabric, a nylon nonwoven fabric and an acrylic nonwoven fabric; a nonwoven fabric impregnated with a resin, such as a polyester nonwoven fabric impregnated with a polyurethane; a polymer resin foam, such as a polyurethane foam and a polyethylene foam; a rubber resin, such as a butadiene rubber and an isoprene rubber; and a photosensitive resin.

As an example of means for adhering the polishing layer to the cushion sheet, there can be mentioned a method in which a double sided tape is sandwiched between the polishing layer and cushion sheet, followed by pressing.

The double sided tape has a common construction in which adhesive layers are provided on both sides of a substrate (such as a nonwoven fabric or a film).

Considering prevention of permeation of a slurry into the cushion sheet and the like, use of a film as the substrate is preferred. Examples of compositions of the adhesive layer include a rubber-based adhesive, an acrylic-based adhesive and the like. Considering the metal ion content, an acrylic-based adhesive is preferred because of low metal ion content. The composition of the polishing layer may be different from that of the cushion sheet. Therefore, the compositions of the adhesive layers of the double sided tape may be different from each other for adjustment of adhesive force of each adhesive layer.

A double sided tape may be provided on the surface of the polishing pad of the present invention to be adhered to a platen. Substantially the same double sided tape as described above, i.e., the double sided tape having a common construction in which adhesive layers are provided on both sides of a substrate, can be used. Examples of substrates include those of a nonwoven fabric, a film and the like. Considering removal of the polishing pad after the use from the platen, use of a film as the substrate is preferred. Examples of compositions of the adhesive layer include a rubber-based adhesive, an acrylic-based adhesive and the like. Considering the metal ion content, an acrylic-based adhesive is preferred because of low metal ion content.

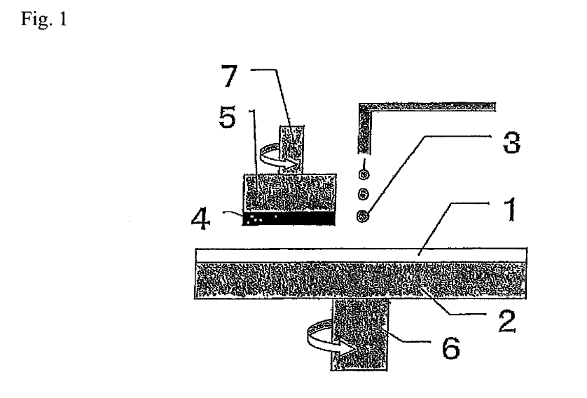

A semiconductor device is produced with a step of polishing the surface of a semiconductor wafer using the above-mentioned polishing pad. Generally, a semiconductor wafer is a silicon wafer having laminated thereon a wiring metal and an oxide film. There is no particular limitation with respect to the method or apparatus for polishing the semiconductor wafer. The polishing is conducted by a method using, for example, an apparatus as shown in FIG. 1, i.e., an apparatus equipped with polishing platen 2 supporting polishing pad (polishing layer) 1, carrier (polishing head) 5 holding semiconductor wafer 4, a backing material for uniformly applying pressure against the wafer and a mechanism for supplying polishing agent 3. Polishing pad 1 is mounted on polishing platen 2 by adhesion with a double sided tape. Polishing platen 2 and polishing head 5 (having rotary shafts 6 and 7, respectively) are appropriately arranged so that polishing pad 1 supported by the former and semiconductor wafer 4 held by the latter are opposed. A pressurizing mechanism for pressing semiconductor wafer 4 to polishing pad 1 is installed on carrier 5. During the polishing, polishing is conducted while pressing semiconductor wafer 4 to polishing pad 1, rotating polishing platen 2 and polishing head 5 and feeding a slurry. There is no particular limitation with respect to the flow of the slurry, load of polishing, number of revolutions of the polishing platen and number of revolutions of the wafer, and these values are properly adjusted.

In this manner, protrusions on the surface of semiconductor wafer 4 are removed and the surface is polished to planar state. Then, the resultant polished wafer is subjected to dicing, bonding, packaging and the like to thereby produce a semiconductor device. The semiconductor device is used in an arithmetic processor, memory and the like.

### EXAMPLES

Hereinbelow, the present invention will be described with reference to Examples. The present invention is not limited to the scope of these Examples.

[Measurement and Evaluation]

### (Measurement of Average Cell Diameter)

A polyurethane resin foam produced was sliced parallel as thinly as possible (with the thickness of 1 mm or less) using a microtome cutter, to thereby obtain samples for measurement. A surface of a sample was photographed with a scanning electron microscope (S-3500N, manufactured and sold by Hitachi Science Systems Co., Ltd.) at 100-fold magnification. An equivalent circular diameter of each cell in an arbitrary area was measured using an image analyzing soft (manufactured and sold by MITANI Corp. with a trade name WIN-ROOF), and an average cell diameter was calculated from the measured values.

(Measurement of Specific Gravity)

Measurement was conducted according to JIS Z8807-1976. A polyurethane resin foam produced was cut out into a strip of 4 cm×8.5 cm (thickness: arbitrary), and this strip was used as a sample for measurement of specific gravity. The sample was left to stand in an environment of a temperature of 23±2° C. and a humidity of 50%±5% for 16 hours. Measurement was conducted using a gravimeter (manufactured and sold by Sartorius Co., Ltd).

(Measurement of Hardness)

Measurement was conducted according to JIS K6253-1997. A polyurethane resin foam produced was cut out into a piece of 2 cm×2 cm (thickness: arbitrary), and this piece was used as a sample for measurement of hardness. The sample was left to stand in an environment of a temperature of 23±2° C. and a humidity of 50% 15% for 16 hours. At the time of measurement, several pieces of the samples were stacked up to a thickness of 6 mm or more. Measurement of hardness was conducted using a durometer (ASKER Durometer Type D, manufactured and sold by Kobunshi Keiki Co., Ltd.). Further, substantially the same measurement was conducted also with respect to the samples which were taken out from water after 48-hour immersion, with the surfaces lightly wiped for removing water thereon.

(Evaluation of Polishing Properties)

Using MAT-ARW-8C1A (manufactured and sold by MAT Inc.) as a polishing apparatus, the polishing properties of the produced polishing pad were evaluated. The polishing rate was calculated from the polishing amount during the polishing of a thermal oxide film of 1 μm thick formed on a silicon wafer (diameter: 8 inch) for 60 seconds. Measurement of thickness of the oxide film was conducted using a light interference type film thickness measuring instrument (instrument name: Nanospec, manufactured and sold by Nanometrics Corporation). The polishing was conducted under the conditions wherein a silica slurry (SS12, manufactured by Cabot Corporation) was added as a slurry at a flow rate of 120 ml/min. during polishing, the polishing loading was 4.5 psi, the number of revolutions of the polishing platen was 93 rpm and the number of revolutions of the wafer was 90 rpm.

Planarization properties were evaluated based on a cut amount. A thermal oxide film was deposited to 0.5 μm thick on an 8 inch silicon wafer, and the resultant wafer was subjected to a predetermined patterning, followed by deposition of another oxide film to 1 μm thick with p-TEOS, to thereby produce a wafer with a pattern at an initial step of 0.5 μm. This wafer was subjected to polishing under the conditions described above and, after the polishing, the difference in height at each stepped portion in the polished surface was measured and a cut amount was calculated. This cut amount means the cut amount with respect to, in a wafer which experienced patterning with a portion having several lines each having a width of 270 μm arranged in parallel to each other at intervals of 30 μm and another portion having several lines each having a width of 30 μm arranged in parallel to each other at intervals of 270 μm, a portion of the polished surface of the wafer corresponding to the interval of 270 μm measured at the time when the difference in height measured from the top of each of the above-mentioned 2 types of lines in the patterning is less than 2000 Å. Small cut amount at a portion corresponding to the interval of 270 μm means small cut amount at a portion which are not intended to be cut and shows high planarity.

Evaluation of scratches was conducted as follows. Four 8-inch dummy wafers were polished under the conditions described above. Subsequently, a wafer having deposited thereon a 10,000-angstroms thick thermal oxide film was polished for 1 minute, and the resultant polished wafer was subjected to a test using a defect evaluation apparatus manufactured and sold by KLA-Tencor Corporation (Surfscan SP1) to determine how many scratches of 0.19 μm or more were present on the polished wafer.

### Example 1

In a reaction vessel were placed 10.2 parts by weight of 3-isocyanatopropyltriethoxysilane (manufactured and sold by Shin-Etsu Chemical Co., Ltd., KBE-9007), 37.8 parts by weight of toluene diisocyanate (a mixture of 2,4-isomer/2,6-isomer=80/20, TDI-80), 22.6 parts by weight of polycaprolactonetriol (manufactured and sold by Daicel Chemical Industries, Ltd., hydroxyl group value: 305 mgKOH/g, number of functional groups: 3), 26.5 parts by weight of a polytetramethylene ether glycol having a number average molecular weight of 650 (PTMG650) and 2.9 parts by weight of diethylene glycol (DEG) (NCO Index: 1.9), and the resultant mixture was allowed to react at 70° C. for 3 hours, to thereby obtain an alkoxysilyl group-containing, isocyanate-terminated prepolymer (% by weight of NCO: 9.12% by weight, hereinbelow referred to as the “Si-prepolymer”).

To a reaction vessel were added 75 parts by weight of a polyether-based prepolymer (manufactured and sold by Uniroyal Chemical Co., Adiprene L-325), 25 parts by weight of Si-prepolymer produced above and 3 parts by weight of a silicone-based surfactant (manufactured and sold by Goldschmidt Chemical Corporation, B8465). These compounds were mixed, and the temperature was adjusted to 70° C. and defoaming was conducted under reduced pressure. Then, vigorous stirring was conducted for approximately 4 minutes using a stirring blade at a number of revolutions of 900 rpm for causing incorporation of a gas to form gas bubbles. Then, 26.4 parts by weight of 4,4′-methylenebis(o-chloroaniline) (hereinbelow referred to as “MOCA”) preliminarily melted at 120° C. was added to the reaction vessel (NCO Index: 1.1). The resultant mixed liquid was stirred for approximately 70 seconds and poured into a loaf-shaped open mold (casting vessel). This mixed liquid was placed in an oven at the point of time of lost of its fluidity and subjected to postcuring at 100° C. for 16 hours, to thereby obtain a polyurethane resin foam block.

The polyurethane resin foam block described above was heated to approximately 80° C. and sliced using a slicer (manufactured and sold by Amitec Corporation, VGW-125), to thereby obtain a polyurethane resin foam sheet. Subsequently, the surface of the sheet was buffed with a buffing machine (manufactured and sold by Amitec Corporation) until the sheet had a thickness of 1.27 mm, to thereby obtain a sheet with an adjusted thickness accuracy. The buffed sheet was punched to form a disc with a diameter of 61 cm, and the surface of the disc was processed using a grooving machine (manufactured by and sold Techno Corporation) for forming concentric circular grooves each with a width of 0.25 mm, a pitch of 1.50 mm and a depth of 0.40 mm, to thereby obtain a polishing layer. To another side of this polishing layer which is opposite to the side which experienced this process for forming grooves, a double-faced adhesive tape (manufactured and sold by Sekisui Chemical Co., Ltd., Double Tack Tape) was applied using a laminator. Further, a cushion sheet (manufactured and sold by Toray Industries, Inc., Toraypef, a polyethylene foam, thickness: 0.8 μm) was corona-treated and the surface of this sheet was buffed. Then, this sheet and a double-faced adhesive tape were stuck together using a laminator. Further, another double-faced adhesive tape was applied on another side of the cushion sheet using a laminator, to thereby produce a polishing pad.

### Examples 2 to 8 and Comparative Examples 1 to 3

Substantially the same procedure as in Example 1 was repeated, except that the compositions given in Table 1 were employed, to thereby produce polishing pads. The hydrophilic prepolymer mentioned in Table 1 was produced as follows.

In a reaction vessel were placed 40 parts by weight of a polyethylene glycol (PEG, manufactured and sold by DKS Co. Ltd., number average molecular weight: 1000), 12.8 parts by weight of another polyethylene glycol (PEG, manufactured and sold by DKS Co. Ltd., number average molecular weight: 600) and 6 parts by weight of DEG, and the resultant mixture was dehydrated for 1 to 2 hours with stirring under reduced pressure. Subsequently, nitrogen was introduced into a separable flask for nitrogen replacement, and TDI-80 (41.2 parts by weight) was added. The resultant mixture was stirred until the reaction was completed with the temperature of the reaction system around 70° C. The reaction was regarded as being completed at the point of time when NCO % became constant (% by weight of NCO: 9.96% by weight). Subsequently, defoaming was conducted for approximately 2 hours under reduced pressure, to thereby obtain the hydrophilic prepolymer.

TABLE 1

| | | Exam- | Exam- | Exam- | Exam- | Exam- | Exam- |
|---|---|---|---|---|---|---|---|
| Production of a polishing pad | | ple 1 | ple 2 | ple 3 | ple 4 | ple 5 | ple 6 |
| Prepolymer | Adiprene L-325 (parts by weight) | 75 | 50 | 25 | 0 | 60 | 40 |
| | Hydrophilic prepolymer (parts by weight) | 0 | 0 | 0 | 0 | 20 | 20 |
| | Si-prepolymer (parts by weight) | 25 | 50 | 75 | 100 | 20 | 40 |
| MOCA (parts by weight) | | 26.4 | 26.4 | 26.4 | 26.4 | 27.5 | 27.5 |
| B8465 (parts by weight) | | 3 | 3 | 3 | 3 | 3 | 3 |
| the content of the alkoxysilyl group-containing isocyanate (% by weight) | | 1.97 | 3.94 | 5.91 | 7.88 | 1.56 | 3.13 |
| Index [NCO]/[NH₂] | | 1.1 | 1.1 | 1.1 | 1.1 | 1.1 | 1.1 |
| Physical | Average cell diameter (μm) | 48 | 46 | 49 | 48 | 48 | 50 |
| properties | Specific gravity | 0.805 | 0.797 | 0.798 | 0.801 | 0.801 | 0.807 |
| | D hardness (degree) | 53 | 54 | 55 | 55 | 56 | 56 |
| | D hardness after 48-hour immersion (degree) | 40 | 42 | 43 | 43 | 43 | 41 |
| | Polishing rate (Å/min.) | 3525 | 3640 | 3625 | 3745 | 3745 | 3645 |
| | Cut amount (Å) | 2500 | 2400 | 2250 | 2300 | 2350 | 2500 |
| | Scratches (per wafer) | 35 | 38 | 42 | 41 | 41 | 56 |

| | | | | Compar- | Compar- | Compar- |
|---|---|---|---|---|---|---|
| | | | | ative | ative | ative |
| | | Exam- | Exam- | Exam- | Exam- | Exam- |
| Production of a polishing pad | | ple 7 | ple 8 | ple 1 | ple 2 | ple 3 |
| Prepolymer | Adiprene L-325 (parts by weight) | 20 | 0 | 100 | 80 | 0 |
| | Hydrophilic prepolymer (parts by weight) | 20 | 20 | 0 | 20 | 100 |
| | Si-prepolymer (parts by weight) | 60 | 80 | 0 | 0 | 0 |
| MOCA (parts by weight) | | 27.5 | 27.5 | 26.2 | 29.7 | 28.7 |
| B8465 (parts by weight) | | 3 | 3 | 3 | 3 | 3 |
| the content of the alkoxysilyl group-containing isocyanate (% by weight) | | 4.69 | 6.77 | 0 | 0 | 0 |
| Index [NCO]/[NH₂] | | 1.1 | 1.1 | 1.1 | 1.1 | 1.1 |
| Physical | Average cell diameter (μm) | 50 | 50 | 46 | 48 | 48 |
| properties | Specific gravity | 0.805 | 0.801 | 0.800 | 0.804 | 0.807 |
| | D hardness (degree) | 55 | 57 | 52 | 53 | 55 |
| | D hardness after 48-hour immersion (degree) | 40 | 43 | 40 | 41 | 17 |
| | Polishing rate (Å/min.) | 3587 | 3640 | 3225 | 3250 | 3350 |
| | Cut amount (Å) | 2500 | 2400 | 2500 | 2550 | 4550 |
| | Scratches (per wafer) | 35 | 47 | 145 | 135 | 52 |

The polishing pad of each of Examples 1 to 8 exhibited high polishing rate and excellent planarization properties. Further, effective control of occurrence of scratch on a wafer was achieved. On the other hand, the polishing pad of each of Comparative Examples 1 to 3 exhibited unsatisfactory polishing rate and planarization properties. Further, in the polishing pad of each of Comparative Examples 1 and 2, effective control of occurrence of scratch on a wafer could not be achieved.

### INDUSTRIAL APPLICABILITY

The polishing pad of the present invention enables planarization processing, stably with high polishing efficiency, of a material which requires high surface planarity, such as optical materials (such as a lens and reflecting mirror), a silicon wafer, an aluminum substrate and common metal polishings. The polishing pad of the present invention can be preferably used especially for a step of planarizing a device with a silicon wafer having formed thereon an oxide layer, a metal layer and the like prior to further laminating (forming) these layers.

### EXPLANATIONS OF LETTERS OR NUMERALS

1: Polishing pad (polishing layer)
2: Polishing platen
3: Polishing agent (slurry)
4: Object to be polished (semiconductor wafer)
5: Carrier (polishing head)
6, 7: Rotating shaft

1. A polishing pad having a polishing layer of a polyurethane resin foam, wherein a polyurethane resin used as a material for forming said polyurethane resin foam has, as a side chain, an alkoxysilyl group represented by general formula (1) below: 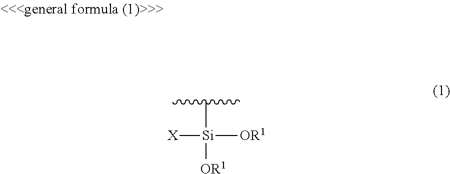
wherein X represents OR¹ or OH, and R¹'s independently represent an alkyl group having 1 to 4 carbon atoms.

2. The polishing pad according to claim 1, wherein said polyurethane resin is a product of curing reaction of a polyurethane raw material composition comprising an alkoxysilyl group-containing, isocyanate-terminated prepolymer and a chain extender,
wherein said alkoxysilyl group-containing, isocyanate-terminated prepolymer is a product of reaction of a prepolymer raw material composition comprising:
an isocyanate component comprising an alkoxysilyl group-containing isocyanate represented by general formula (2) below: 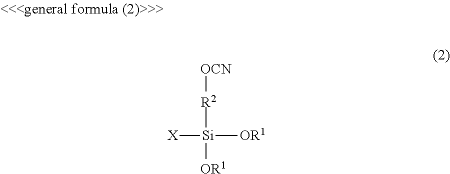
wherein X represents OR¹ or OH, R¹'s independently represent an alkyl group having 1 to 4 carbon atoms, and R² represents an alkylene group having 1 to 6 carbon atoms, and
a polyol component comprising a polyol having a functionality of 3 or more.

3. The polishing pad according to claim 2, wherein said alkoxysilyl group-containing isocyanate is 3-isocyanatopropyltriethoxysilane.

4. The polishing pad according to claim 2 or 3, wherein the content of said alkoxysilyl group-containing isocyanate is 1 to 10% by weight based on said polyurethane raw material composition.

5. A method for producing a polishing pad comprising mixing a first component comprising an isocyanate-terminated prepolymer and a second component comprising a chain extender for curing to thereby produce a polyurethane resin foam,
wherein said first component comprises an alkoxysilyl group-containing, isocyanate-terminated prepolymer which is a product of reaction of a prepolymer raw material composition comprising:
an isocyanate component comprising an alkoxysilyl group-containing isocyanate represented by general formula (2) below: 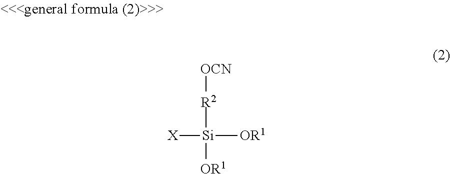
wherein X represents OR¹ or OH, R¹'s independently represent an alkyl group having 1 to 4 carbon atoms, and R² represents an alkylene group having 1 to 6 carbon atoms, and
a polyol component comprising a polyol having a functionality of 3 or more, and
wherein, in said mixing, a silicone-based surfactant is added to said first component in an amount of 0.05 to 10% by weight based on the total weight of said first and second components, said first component is stirred with a non-reactive gas to thereby prepare a gas bubble-dispersed liquid having dispersed therein gas bubbles of said non-reactive gas, and said second component is added to said gas bubble-dispersed liquid for curing to thereby produce a polyurethane resin foam.

6. The method for producing a polishing pad according to claim 5, wherein said alkoxysilyl group-containing isocyanate is 3-isocyanatopropyltriethoxysilane.

7. The method for producing a polishing pad according to claim 5 or 6, wherein the content of said alkoxysilyl group-containing isocyanate is 1 to 10% by weight based on the total weight of said first and second components.

8. A method for producing a semiconductor device comprising polishing the surface of a semiconductor wafer using the polishing pad of any one of claims 1 to 4.
